(19) United States
(12) Patent Application Publication
(10) Pub. No.: US 2007/0247239 A1
(43) Pub. Date: Oct. 25, 2007

(54) Phase modulator

(75) Inventors: Jaako O. Maunuksela, Espoo (FI); Mikael Svard, Helsingtors (FI); Ari Vilander, Kerava (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Nokia Corporation

(21) Appl. No.: 11/472,447

(22) Filed: Jun. 22, 2006

(30) Foreign Application Priority Data
Apr. 24, 2006 (FI) 20065260

(51) Int. Cl. H03B 27/00

(52) U.S. Cl. 331/45

(57) ABSTRACT

A modulator, comprising an input unit configured to receive a modulating signal, a control unit configured to provide a control signal on the basis of the modulating signal, an oscillating unit configured to provide a plurality of instances of at least two phase components of a carrier frequency signal, a phase selector configure to select, on the basis of the control signal, a combination of the phase component instances so that an output signal representing the information contents of the modulating signal is obtained, and a combiner configured to combine the selected phase component instances to form a modulated output signal.

### FIELD

The invention relates to a phase modulator and a method of phase modulation. Especially, the invention relates to BP-PWM modulation (band-pass pulse-width modulation).

### BACKGROUND

A current trend in radio transmitter development is driving towards software configurable multimode devices. In order to fulfill stringent multi-radio requirements, new architectural approaches have to be developed. This trend drives towards further digitalization of radio transmitters.

As background to BP-PWM modulation, PWM modulation is first discussed with reference to FIG. 1. The object therein is to control the output digital pulse 106 width by a phase control, which is formed in a low frequency part of a modulator. This can be accomplished by using a phase accumulator which has a high frequency clock. The output of the phase accumulator is a digital saw tooth waveform 100, whose frequency can be controlled by a phase word fed to the accumulator. Saw tooth signals 100 are added to the phase signals 102 originating from the low frequency part. The obtained signal is fed to a comparator, whose comparison points are shown by reference 104 in FIG. 1. The output of the comparison is a square wave 106, whose duty cycle is proportional to the phase value.

In a digital implementation, digital phase and magnitude signals are used for controlling the phase modulator. Phase modulation is performed on a carrier frequency signal, which typically has a frequency of around 1-2 GHz. The quality of the modulated signal is proportional to the resolution of the output signal phase. Based on system simulations, practically 8-bit accuracy is needed for the control signal to meet the requirements for a WCDMA-signal (wideband code division multiple access). This corresponds to 1.4 degree phase accuracy for a 2-GHz carrier signal. For digital implementation, this means approximately 2-ps time resolution. In a digital delay line, a 500-GHz clock frequency is needed, which is a disadvantage in view of a digital implementation.

A transmitter utilizing the BP-PWM type of modulation is a recently developed new architectural approach. System simulations have shown that in a fully digital realization, some critical components have so stringent requirements that they are very difficult to implement.

In BP-PWM modulation, the modulating signal, which carries modulating information, is converted to polar domain, to phase and magnitude signals. The modulating signal is first pre-distorted and then used for controlling the place of the BP-PWM signal edges. In other words, the signal's phase and magnitude are coded into those signal edges. Generally, any type of digital or analogue phase modulator can be used for controlling the pulse edges if they have a required control bandwidth and output resolution. Currently, there are no feasible solutions for a highly preferred fully digital implementation.

One prior art digital approach is disclosed in U.S. Pat. No. 6,993,087, which is incorporated herein by reference. Such an approach is also illustrated by FIG. 2, where a clock signal from a system clock 200 is provided. The clock signal is fed to a delay line, providing 16 different delay values for the clock signal. For each clock cycle, one of the 16 possibilities is chosen and the delayed high-frequency signal is transferred via a bus 204 to a multiplexer 206 to be multiplexed with a modulating signal.

A drawback in the known digital approach for providing a phase shifted BP-PWM signal is the need for a high frequency clock. In order to achieve good modulation quality, the clock needs to be roughly 256 times the carrier frequency, which means the order of the 2-picosecond clock cycle in a WCDMA implementation, for instance.

### BRIEF DESCRIPTION

It is thus an object of the invention to provide an accurate phase modulator without the need for a high-frequency clock.

In one aspect of the invention there is provided a modulator, comprising an input unit configured to receive a modulating signal, a control unit configured to provide a control signal on the basis of the modulating signal, an oscillating unit configured to provide a plurality of instances of at least two phase components of a carrier frequency signal, a phase selector configured to select, on the basis of the control signal, a combination of the phase component instances so that an output signal representing the information contents of the modulating signal is obtained, and a combiner configured to combine the selected phase component instances to form a modulated output signal.

In another aspect of the invention there is provided a modulator, comprising means for receiving a modulating signal, means for providing a control signal of the basis on the modulating signal, means for providing a plurality of instances of at least two phase components of a carrier frequency signal, means for selecting, on the basis of the control signal, a combination of the phase component instances so that an output signal representing the information contents of the modulating signal is obtained, and means for combining the selected phase component instances to form a modulated output signal.

In still another aspect of the invention there is provided a modulating method, comprising steps of receiving a modulating signal, providing a control signal of the basis on the modulating signal, providing a plurality of instances of at least two phase components of a carrier frequency signal, selecting, on the basis of the control signal, a combination of the phase component instances so that an output signal representing the information contents of the modulating signal is obtained, and combining the selected phase component instances to form a modulated output signal.

In still another aspect of the invention there is provided a computer program embodied on a computer readable medium, the computer program comprising instructions for receiving a modulating signal, providing a control signal of the basis on the modulating signal, providing a plurality of instances of at least two phase components of a carrier frequency signal, selecting, on the basis of the control signal, a combination of the phase component instances so that an output signal representing the information contents of the modulating signal is obtained, and combining the selected phase component instances to form a modulated output signal.

The preferred embodiments of the invention are disclosed in the dependent claims.

The method and arrangement of the invention provide an accurate phase modulator for a BP-BMW modulator without a need for a high frequency clock.

### DRAWINGS

In the following the invention will be described in greater detail by means of preferred embodiments with reference to the drawings, in which

FIG. 1 highlights already disclosed PWM pulse generation;

FIG. 2 shows already disclosed prior art arrangement for PWM modulation;

FIG. 3 highlights transmitter and receiver operation on a high level;

FIG. 4 shows one embodiment of an apparatus according to the invention;

FIG. 5 shows one example of a signal provided by an apparatus according to the invention;

FIG. 6 shows one embodiment of an apparatus according to the invention;

FIG. 7 shows one embodiment of a part of an apparatus according to the invention;

FIG. 8 shows one embodiment of a part of an apparatus according to the invention;

FIG. 9 shows one embodiment of a part of an apparatus according to the invention, and

FIG. 10 shows one embodiment continuous phase rotation so as to obtain desired output phases;

FIG. 11 shows one embodiment of a method according to the invention.

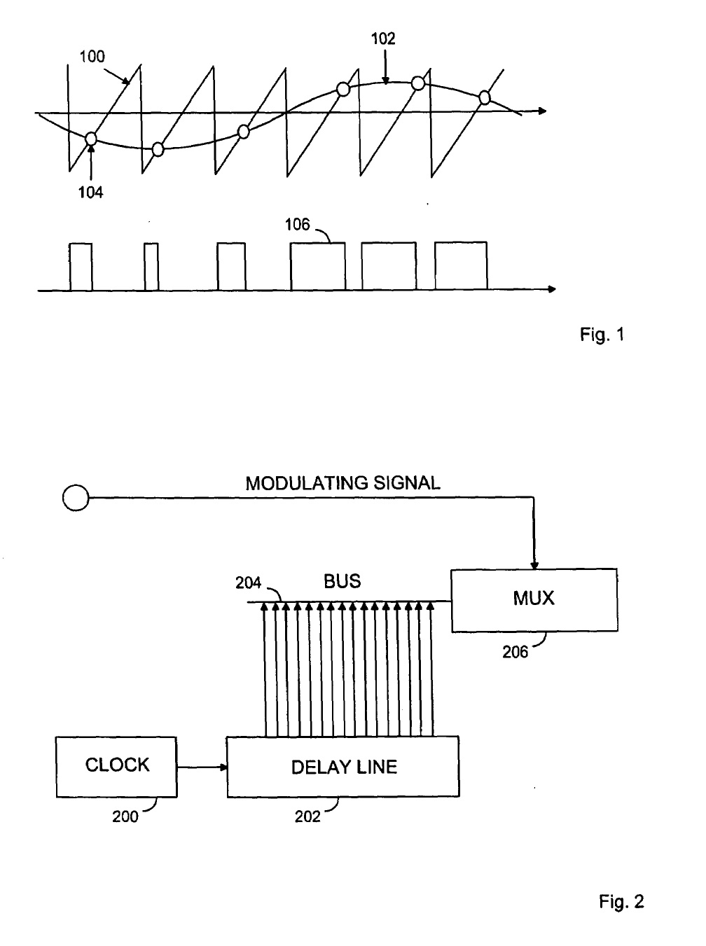

### DETAILED DESCRIPTION

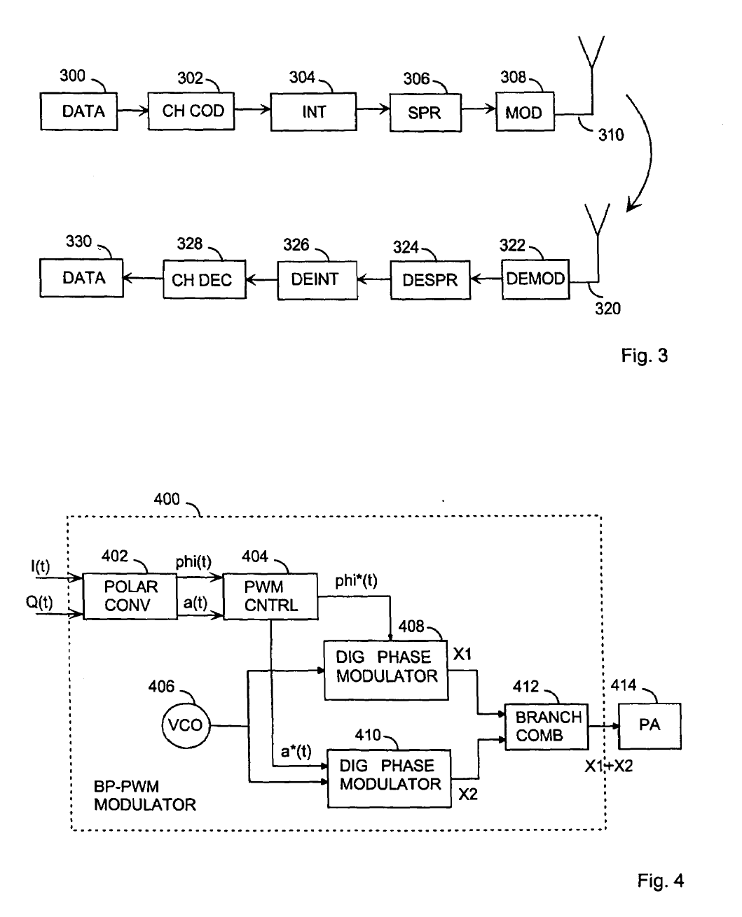

FIG. 3 shows on a general level the principles of a radio transmitter and receiver pair in a WCDMA mobile system, which is one example of a radio system which the invention may be applied to. The radio transmitter may be located in a base station or in a subscriber terminal, and the radio receiver also in a subscriber terminal or in a base station. The upper part of FIG. 3 shows the basic functions of a radio transmitter and the lower part the general structure of the functions performed by a radio transmitter. The information 300 to be transmitted is coded in a channel coder 302 by block coding or convolution coding, for instance. However, the pilot bits to be transmitted are not channel coded, since the intention is to find out the distortions caused to the signal by the channel. After channel coding, the information is interleaved in an interleaver 304. In interleaving, the bits of different services are mixed together in a special manner, whereby a transient fading on the radio path does not necessarily yet render the transferred information unidentifiable. The interleaved bits are spread by a spreading code in block 306. The signal is then applied to a modulator 308, after which the signal is still amplified and filtered before transmission to the radio path via an antenna 310.

The transmitted radio signal is received from the radio path by a receiver antenna 320. After filtering, the received signal is demodulated in block 322, despread in block 324 and deinterleaved in block 326. The channel coding used in the transmission is decoded in a channel decoder 328, whereupon the received data 330 are, in an optimal situation, identical to the transmitted data 300.

FIG. 4 shows one example of a BP-PWM modulator 400 according to the invention. The modulator may be used in a base station of a radio network or in a mobile terminal, such as mobile phone, for instance. The modulator may be embodied on a chipset and the invention may be implemented on the chipset by software, for instance.

The modulator's input unit takes I and Q signals of the original data signal as input. The input signals are converted to polar domain in a converting unit 402, that is conversion is carried out to provide amplitude a(t) and phase phi(t) signals.

The signals in polar domain are predistorted in a PWM control unit 404. In one embodiment, predistorted amplitude signal a*(t) is formed by a*(t)=phi(t)/n+(arcsin(a(t))/n), and the predistorted phase signal phi*(t) is formed by phi*(t)=phi(t)/n−arcsin(a(t))/n, where n is the harmonic signal to which the modulation is mapped. The predistorted control signals are fed to digital phase modulators 408 and 410, which also receive oscillation signals from a local oscillator 406. A branch combiner 412 combines two PPM modulated signals to one BP-PWM signal such that an output signal indicated by the control signals is obtained. Besides summing, other arithmetic operations may be applied as well depending on the process how the pulses are formed. The modulated signal is forwarded to subsequent parts of the transmitter, such as a power amplifier 414.

The modulating system of FIG. 4 is thus configured to provide two pulse position modulated pulse (PPM) trains, where one pulse train is provided on the basis of the predistorted amplitude signal and the other pulse train is provided on the basis of the predistorted phase signal. A BP-PWM signal is formed of differences of pulse pairs, which includes one PPM pulse of each PPM pulse train.

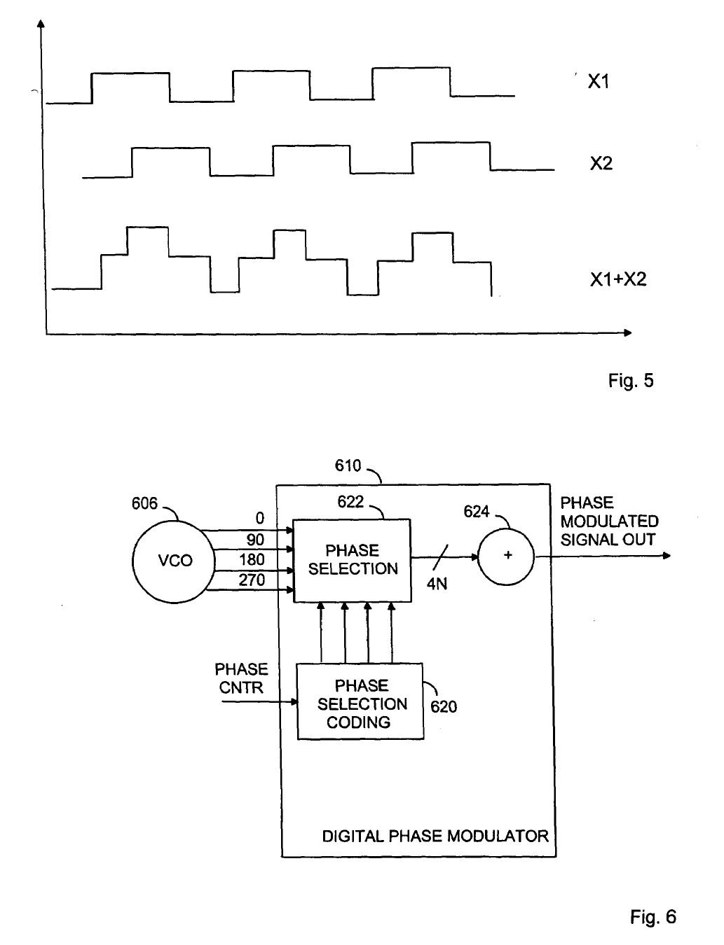

FIG. 5 shows one example of a signal provided by the BP-PWM modulator of FIG. 4. Signals X1 and X2 provided by the respective digital phase modulators are summed to a signal X1+X2, which thereby provides a three-level output.

FIG. 6 shows an embodiment of a digital phase modulator 610 according to the invention. The output of a VCO (voltage controlled oscillator) 606 is divided into a number of output phase components. FIG. 4 shows four components (0, 90, 180, 270 degrees) separated 90 degrees from each other. The four components have been shown only as an example. The number of components may be any number greater than or equal to two. Preferably the number of different components is three or more such that sufficient accuracy for the output phase is obtained, which is the case in QPSK modulation, for instance. Increasing the number of phase components or component branches improves the quality of the output signal, but also increases the amount of control logic to select the branches.

A phase selection coding block 620 takes as input a phase control word, which has been constructed on the basis of the modulating signal. The phase selection coding block 620 provides phase selection control as output to the phase control word. The phase selection control is used for controlling the selection of phase component branches in a phase selection block 622. The selected phase components are combined in a combiner 624 to provide a PPM modulated signal representative of the modulating signal.

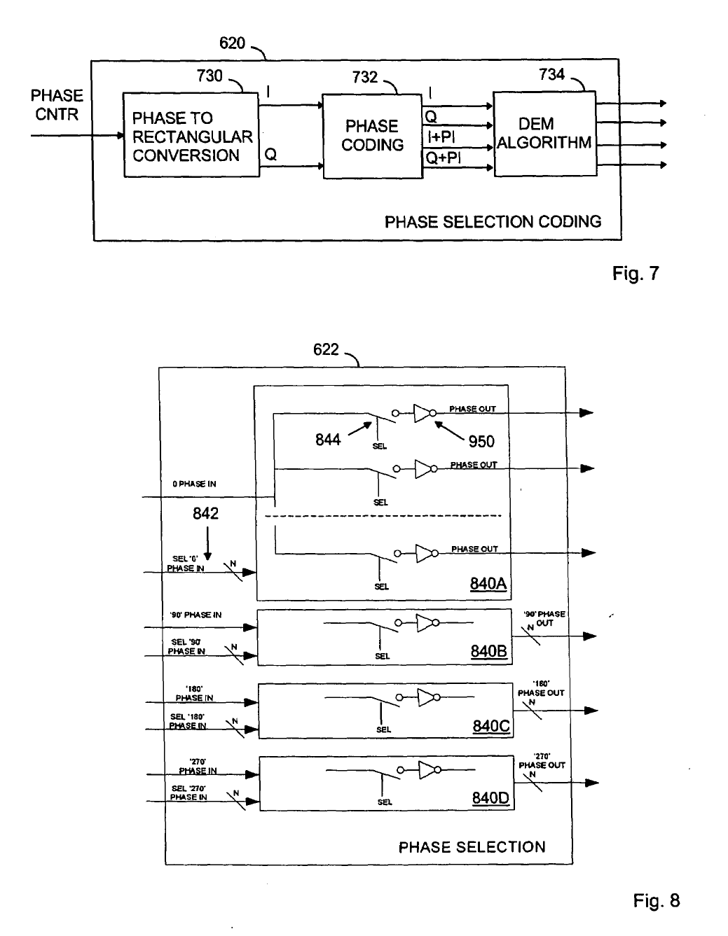

FIG. 7 specifies implementation of the phase selection coding block 620. The inputted phase control word is first converted to I and Q signals in a conversion block 730. I and Q signals are formed by taking a mathematical cos-function and sin-function of the control word respectively. That can be implemented by using a cordic-algorithm or look-up-tables, for instance. Cordic-algorithm is preferred, when high precision is needed.

Phase coding block 732 codes the I and Q signals to phase selection signals. This means that the output phase indicated by the input I and Q-signals is formed as a combination of available phase signals components, which in this case are 0 (I), 90 (Q), 180 (I+PI) and 270 (Q+PI) degrees phase-shifted signal components. As a simple example, an output phase of 45 degrees might be formed by selecting N instances of both 0-degree and 90-degree phase signal components. Thus, the block 732 provides as output which components are needed in the combining of phase components and how many instances of each component are needed. If an output phase greater than the greatest phase component (270 to 360 degrees in this example) is desired, phase components of 270 degrees from a previous cycle and 0 degrees from a next cycle may be used.

After the phase coding block 732, a DEM algorithm (dynamic element matching) 734 is used to arbitrarily select the used phase component branch. Incorporation of the DEM algorithm is advantageous in order to eliminate error introduced by one phase component branch. The reason for the use of a DEM algorithm is that the N branches of the phase components differ slightly from each other due to analog non-idealities. If the same branches are always used, static error is generated, which is always the same for a certain phase angle. For instance, if a certain phase component (e.g. 90-degree) has ten branches, and a certain output phase needs four of these ten branches, these four branches are advantageously selected randomly from the ten branches.

FIG. 8 specifies the phase selection block 622. Inputs for the phase selection block 622 are the phase components from a VCO 606 and a phase selection control signal from a phase selection coding block 620. Each phase component is divided into N branches driven by inverter cells 840A to 840D respective to each phase component (0, 90, 180, 270 degrees).

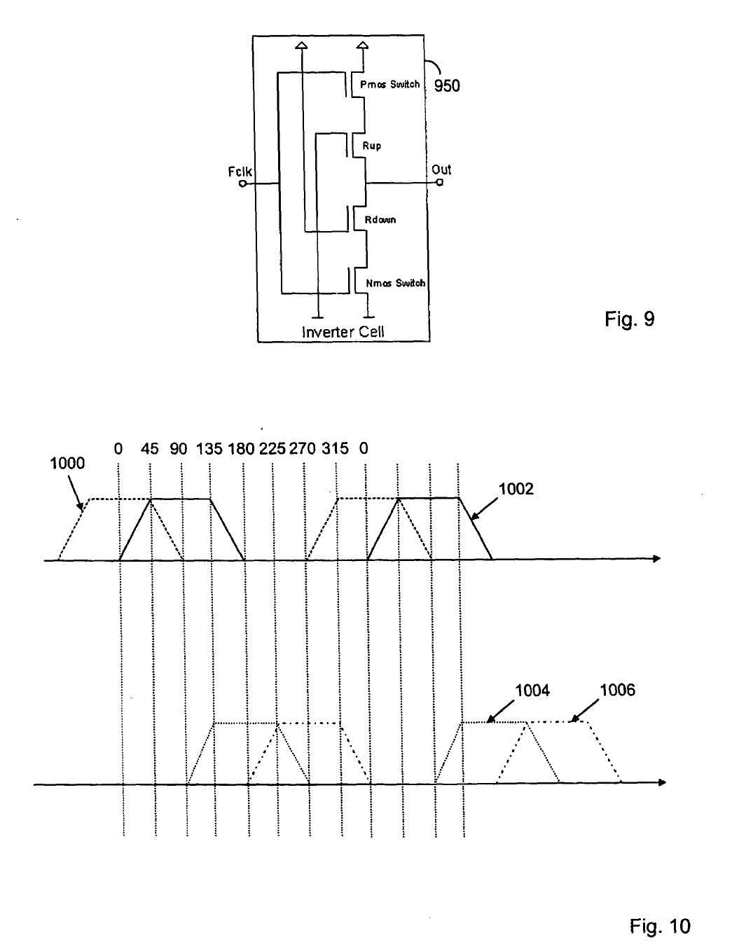

An inverter as shown in FIG. 9 may be formed from PMOS and NMOS switches and current limiting resistors Rᵤₚ and R_{down}. Input to the inverter 950 is enabled with a switch 844 controlled by a phase selection signal 842. The output of each block 840A to 840D is the needed number of phase component braches, which are summed together to realize the wanted output phase. In principle, any kind of switching current source can be used in place of the inverter cell 950. Phase component branches may be summed together at a resonator coil so that the phase of the current pulses determines the resonance frequency of the coil. Any other kind of summing circuit, capable os summing current branches together, may also be used.

FIG. 10 presents an example how control is carried out when continuous phase rotation is performed. There are four different phase components 1000 to 1006. The amplitude of the components presents the number of active branches of that particular phase. When there are the full number of 0-degree phase component branches, the output phase is zero. As the number of 90-degree phase component branches is the same as 0-degree branches, the output phase equals 45 degrees. Using the same analogue for all phase component branches, a full rotation of the output phase can be performed.

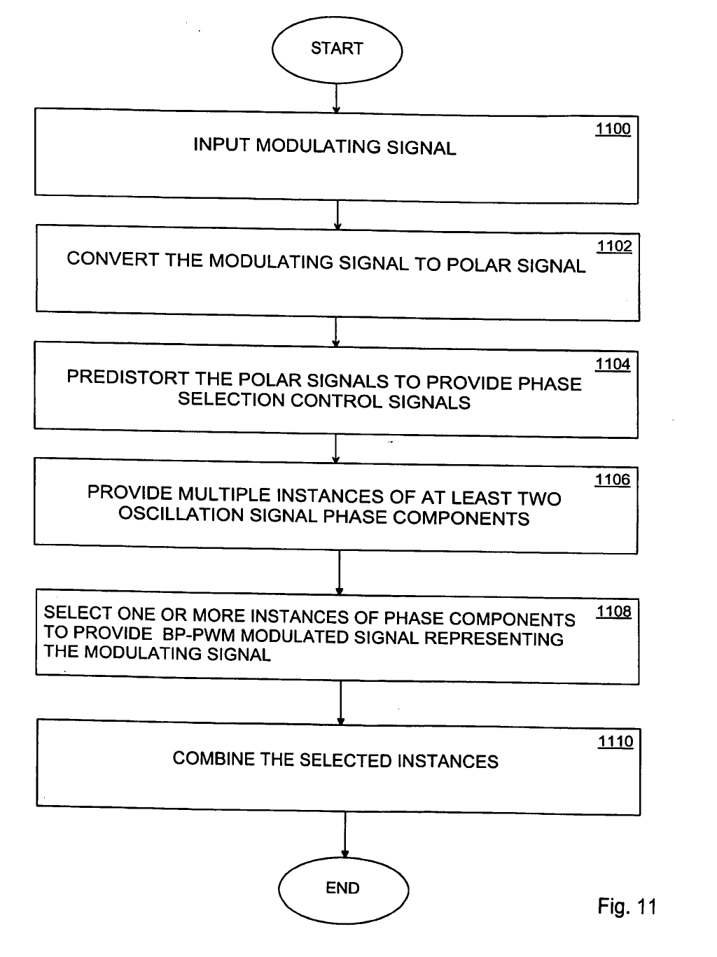

FIG. 11 shows one embodiment of a method according to the invention. In 1100, a modulating signal, including I and Q signal branches, is taken as input. In 1102, the modulating signal is converted into a polar signal, that is signals representing amplitude and phase of the modulating signal. In 1104, the converted signals are predistorted in a way needed by BP-PWM modulation. In 1106, multiple instances of at least two different phase components of an oscillation signal are provided. Advantageously, in QPSK modulation, more than three phase components are provided.

In 1108, a control signal is generated for controlling selection of the number of phase components such that a desired output phase is obtained for a PPM modulated pulse. In one embodiment, the BP-PWM modulated signal is formed from two PPM (Pulse position modulation) signals. The pulses are in 50-50 ratio and the information is coded into the position of the pulse. When the positions of two pulses, one from each PPM signal, are subtracted from each other, the duration/width of a BP-PWM pulse is obtained. In 1110, the selected signals are combined so as to provide a BP-PWM modulated signal representing the information contents of the modulating signal.

In one embodiment, the invention is implemented by software executable on a processor. The software may be packaged into a computer program product, which may be stored on a separate storage medium, which can be read and executed by a computer in a radio transmitter. Alternatively to software, the invention may be implemented by hardware, as ASIC (Application specific integrated circuit) or separate logic components.

It will be obvious to a person skilled in the art that, as the technology advances, the inventive concept can be implemented in various ways. The invention and its embodiments are not limited to the examples described above but may vary within the scope of the claims.

1. A modulator, comprising:
an input unit configured to receive a modulating signal;
a control unit configured to provide a control signal based on the modulating signal;
an oscillating unit configured to provide a plurality of instances of at least two phase components of a carrier frequency signal;
a phase selector configured to select, based on the control signal, a combination of the instances to provide an output signal representing information contents of the modulating signal; and
a combiner configured to combine the instances selected, to form a modulated output signal.

2. A modulator according to claim 1, wherein the input unit is configured to receive I and Q signals of a data signal.

3. A modulator according to claim 1, wherein the control unit comprises:
a polar converter configured to convert the I and Q input signals to a phase signal phi(t) and to an amplitude signal a(t).

4. A modulator according to claim 3, wherein the control unit further comprises:
a predistorter configured to predistort the phase signal and the amplitude signal.

5. A modulator according to claim 4, wherein the phase selector is configured to provide two pulse position modulated pulse trains, wherein a first pulse train of the two pulse trains is provided based on the predistorted amplitude signal and a second pulse train of the two pulse trains is provided based on the predistorted phase signal.

6. A modulator according to claim 4, wherein the predistorter is configured to provide a predistorted amplitude signal a*(t)=phi(t)/n+(arcsin(a(t))/n), wherein t is time and n is a harmonic signal to which modulation is mapped.

7. A modulator according to claim 4, wherein the predistorter is configured to provide a predistorted phase signal phi*(t)=phi(t)/n−arcsin(a(t))/n, wherein t is time and n is a harmonic signal to which modulation is mapped.

8. A modulator according to claim 1, wherein the modulator is configured to provide a band-pass pulse width modulation signal as the modulated output signal.

9. A modulator according to claim 8, wherein the band-pass pulse width modulation signal is provided by a difference of two pulse position modulated signals.

10. A modulator according to claim 8, wherein the oscillating unit is configured to provide at least three phase components.

11. A base station, comprising a modulator according to claim 1.

12. A mobile terminal comprising a modulator according to claim 1.

13. A modulator, comprising:
means for receiving a modulating signal;
means for providing a control signal based on the modulating signal;
means for providing a plurality of instances of at least two phase components of a carrier frequency signal;
means for selecting, based on the control signal, a combination of the instances to provide an output signal representing information contents of the modulating signal; and
means for combining the instances selected, to form a modulated output signal.

14. A modulating method, comprising:
receiving a modulating signal;
providing a control signal based on the modulating signal;
providing a plurality of instances of at least two phase components of a carrier frequency signal;
selecting, based on the control signal, a combination of the instances to provide an output signal representing information contents of the modulating signal; and
combining the instances selected, to form a modulated output signal.

15. A computer program embodied on a computer readable medium, the computer program being configured to:
receive a modulating signal;
provide a control signal based on the modulating signal;
provide a plurality of instances of at least two phase components of a carrier frequency signal;
select, based on the control signal, a combination of the instances to provide an output signal representing information contents of the modulating signal; and
combine the instances selected, to form a modulated output signal.
